(19) United States
(12) Patent Application Publication
(10) Pub. No.: US 2023/0396182 A1
(43) Pub. Date: Dec. 7, 2023

(54) POWER CONVERSION DEVICE

(71) Applicants: KABUSHIKI KAISHA KOSHIBA, Tokyo (JP); TOSHIBA INFRASTRUCTURE SYSTEMS & SOLUTIONS CORPORATION, Kawasaki-shi Kanagawa (JP)

(72) Inventors: Hiroomi SUZUKI, Koshigaya Saitama (JP); Tsunehito FUJITA, Koganei Tokyo (JP)

(73) Assignees: KABUSHIKI KAISHA KOSHIBA, Tokyo (JP); TOSHIBA INFRASTRUCTURE SYSTEMS & SOLUTIONS CORPORATION, Kawasaki-shi Kanagawa (JP)

(21) Appl. No.: 18/032,785

(22) PCT Filed: Oct. 20, 2021
(86) PCT No.: PCT/JP2021/038822

§ 371 Date: Apr. 19, 2023

(30) Foreign Application Priority Data
Oct. 22, 2020 (JP) 2020-177336

(51) Int. Cl. H02M 7/00; H02M 7/48; H01F 27/08

(52) U.S. Cl. CPC H02M 7/003; H02M 7/4815; H01F 27/085

(57) ABSTRACT

A power conversion device according to an embodiment includes: a housing; a panel-shaped unit frame detachably attached to the housing such that an inside of the housing is sealed; a transformer and a cooler attached to one face of the unit frame and outside the housing, with the unit frame attached to the housing; an electronic component attached to another face of the unit frame and inside the housing, with the unit frame attached to the housing; and a flat conductive member electrically connecting the transformer and the electronic component, inside the housing.

### FIELD

Embodiments of the present invention relate to power conversion devices.

### BACKGROUND

An electric railway vehicle has a floor on or under which a vehicular power conversion device is provided.

For power supply to each device in the vehicle, the vehicular power conversion device performs power conversion, with a switching element on the input side, to power taken in from an overhead line, conversion to a predetermined voltage through a transformer, and conversion to direct-current power with a switching element on the output side.

In this case, adopted is a configuration in which the switching element on the input side and the transformer are connected through a conductor and the transformer and the switching element on the output side are connected through a conductor.

In general, a transformer generates heat at the time of conversion to voltage. Thus, for cooling, such a transformer is desirably installed in open space (open part) outside a housing.

Meanwhile, a switching element is an electronic component. Thus, for protection against dust or the like, such a switching element is desirably installed in a sealed space (sealed part) inside a housing.

Therefore, a conductor connecting a transformer and a switching element is disposed through an insertion hole provided at a partition at the boundary between open part and a sealed part.

In this case, induction heating is likely to occur due to the material of the partition or deterioration is likely to occur in maintenance due to a complicated structure in which the insertion hole is filled with a sealing member for protection of the sealed part from dust.

In order to solve such problems, a simple configuration has been proposed in which a switching element to which a conductor is connected is molded with an insulating member in a first housing and a transformer connected to the conductor is housed in a second housing such that the transformer is partially exposed to the open air.

### CITATION LIST

### Patent Literature

Patent Literature 1: WO 2017/141422 A

### SUMMARY OF THE INVENTION

Problem to be Solved by the Invention

In a case where the structure described above is applied to the housing of a power conversion device, a switching element is molded with an insulating member. This leads to another problem that the switching element is difficult to change at the time of trouble.

For achievement of a small-sized transformer, use of a high-frequency transformer is conceivable as a transformer.

However, because of a flow of high-frequency current between the switching element and the transformer, the shortest possible wiring length is required to suppress heat generation and inductance.

Furthermore, the switching element and the transformer are housed in respective different housings, leading to a complicated structure.

The present invention has been made in consideration of the above, and an object of the present invention is to provide a power conversion device that can secure both the sealing performance for a switching element and the cooling performance for a transformer, with a simple configuration.

### Means for Solving Problem

A power conversion device according an the embodiment includes: a housing; a panel-shaped unit frame detachably attached to the housing such that an inside of the housing is sealed; a transformer and a cooler attached to one face of the unit frame and outside the housing, with the unit frame attached to the housing; an electronic component attached to another face of the unit frame and inside the housing, with the unit frame attached to the housing; and a flat conductive member electrically connecting the transformer and the electronic component, inside the housing.

### BRIEF DESCRIPTION OF DRAWINGS

FIG. 1 is an explanatory view of a schematic configuration of a vehicular power conversion device according to a first embodiment.

FIG. 2 is a partial sectional view in a case where a power conversion unit is removed from a control box.

FIG. 3 is a circuit diagram of the vehicular power conversion device.

FIG. 4 is a bottom plan view of a unit frame in the first embodiment.

FIG. 5 is a side view of a power conversion unit in a second embodiment.

FIG. 6 is a bottom plan view of a unit frame in the second embodiment.

FIG. 7 is an explanatory view in a modification to the embodiments.

### DETAILED DESCRIPTION

Embodiments will be described below with reference to the drawings.

### [1] First Embodiment

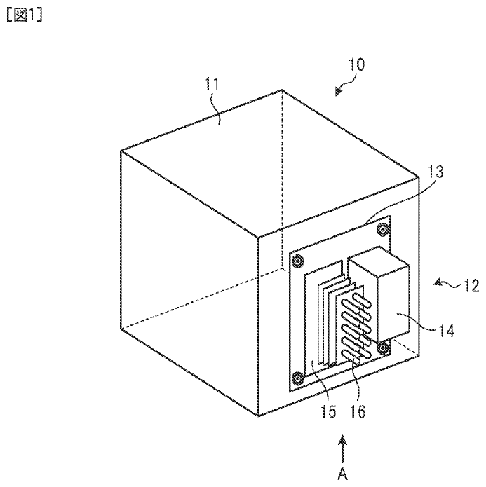

FIG. 1 is an explanatory view of a schematic configuration of a vehicular power conversion device according to a first embodiment.

A vehicular power conversion device 10 includes a control box 11 and a power conversion unit 12.

The power conversion unit 12 includes a unit frame 13, a high-frequency transformer (transformer) 14, a cooler base 15, and a cooler (cooling fin unit) 16.

In the above configuration, with the unit frame attached, the inside of the control box 11 forms a sealed space. In this case, the control box 11 and the unit frame 13 are fastened with bolts, and can be easily unfastened at the time of maintenance.

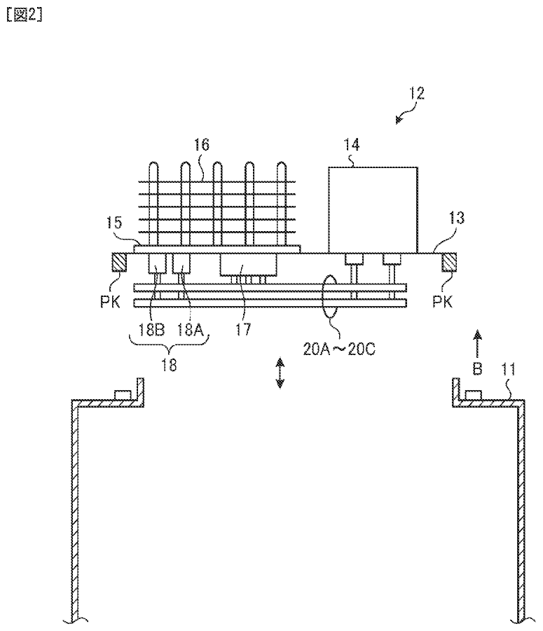

FIG. 2 is a partial sectional view in a case where the power conversion unit is removed from the control box.

Referring to FIG. 2, the main part of the high-frequency transformer 14 (excluding its terminal part), the cooler base 15, and the cooler 16 are disposed on the top side of the unit frame 13 of the power conversion unit 12.

A packing PK disposed along the circumference of the unit frame, a switching element unit 17 disposed in close contact with the cooler base 15, and a diode unit 18 disposed in close contact with the cooler base 15 are disposed on the back side of the unit frame 13.

In addition, as described below, thin flat conductors 20A to 20C establishing electric connection between each part are disposed on the lower side of the switching element 17 and the diode unit 18.

The configuration of an electric circuit of the vehicular power conversion device 10 will be now described.

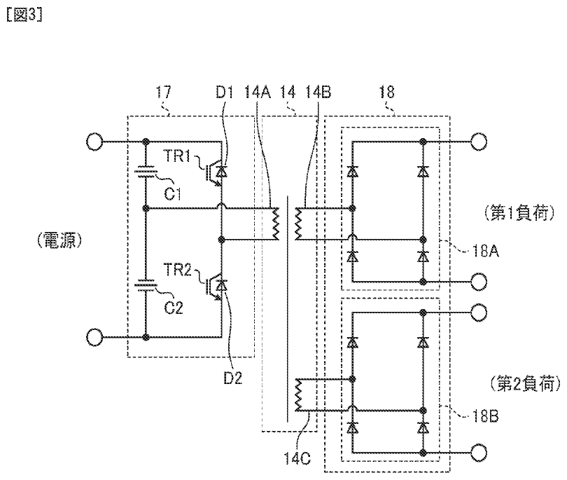

FIG. 3 is a circuit diagram of the vehicular power conversion device.

The switching element unit 17 of the vehicular power conversion device 10 is formed as a resonance single-phase half-bridge inverter and includes resonance capacitors C1 and C2 connected in series between power-source lines, switching transistors TR1 and TR2 connected in series between the power-source lines, and parasitic diodes D1 and D2.

In the above configuration, the node between the resonance capacitor C1 and the resonance capacitor C2 and the node between the switching transistor TR1 and the switching transistor TR2 are each connected to a primary wiring 14A of the high-frequency transformer 14.

The diode unit 18 includes a first diode rectifier 18A having its input terminal connected to a secondary wiring 14B of the high-frequency transformer 14 and its output terminal connected to a first load and a second diode rectifier 18B having its input terminal connected to a tertiary wiring 14C of the high-frequency transformer 14 and its output terminal connected to a second load.

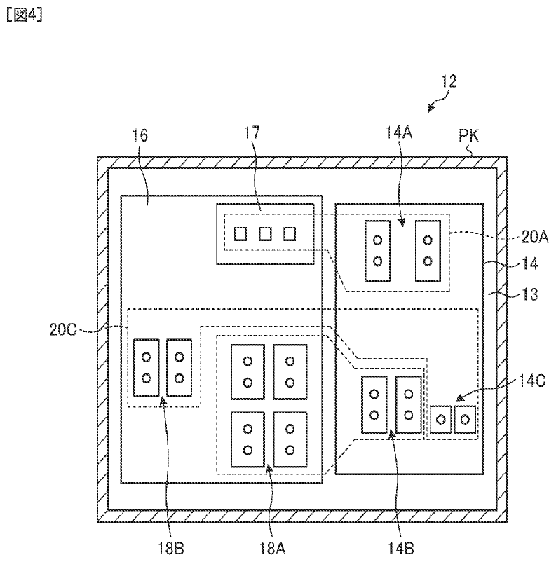

FIG. 4 is a bottom plan view of the unit frame in the first embodiment.

Referring to FIG. 4, for easy understanding, the thin flat conductors 20A to 20C are displayed in a see-through manner with dashed lines.

Terminals corresponding to the primary wiring 14A of the high-frequency transformer 14, terminals corresponding to the secondary wiring 14B of the high-frequency transformer 14, and terminals corresponding to the tertiary wiring 14C of the high-frequency transformer 14 protrude on the bottom side of the unit frame 13 of the power conversion unit 12. In this case, because of larger electric energy, the terminals corresponding to the primary wiring 14A and the number of terminals of wiring corresponding to the secondary wiring 14B (four each in the example of FIG. 4) are larger than the number of terminals of the tertiary wiring (two in the example of FIG. 4).

The switching element unit 17 disposed in close contact with the cooler base 15 has three terminals protruding in the example of FIG. 4. Then, the terminals of the switching element unit 17 and the terminals corresponding to the primary wiring 14A are electrically connected through the thin flat conductor 20A.

Eight terminals of the first diode rectifier 18A and the terminals of the secondary wiring 14B are electrically connected through the thin flat conductor 20B.

Furthermore, four terminals of the second diode rectifier 18B and the terminals of the tertiary wiring 14C are electrically connected through the thin flat conductor

As illustrated in FIG. 4, the thin flat conductor 20A and the thin flat conductor 20B regarded as larger in flowing electric energy than the thin flat conductor 20C each have a shorter length of wiring than that of the thin flat conductor 20C.

Thus, suppression can be made in the quantity of heat generation and in inductance.

As described above, according to the present first embodiment, the electric components constituting the power conversion device are made as a single power conversion unit, so that the electric components are disposed physically close to each other, leading to shorter lengths of conductors. That is, because of shorter lengths of current paths, an improvement can be made in conversion efficiency with suppression in the quantity of heat generation and suppression in inductance, leading to a reduction in power consumption.

From among the component terminals of the electric components constituting the power conversion unit 12, terminals corresponding to a current path for larger electric energy are disposed physically close to each other for a shorter length of conductor, namely, for a shorter length of current path.

Therefore, an improvement can be made in conversion efficiency with suppression in the quantity of heat generation and suppression in inductance, leading to a reduction in power consumption.

Furthermore, the temperature inside the control box 11 can be inhibited from rising.

Disposition of the electronic components in the sealed part and disposition of the transformer large in heat generation in the open part can be both made, leading to a reliable and long-life power conversion unit.

### [2] Second Embodiment

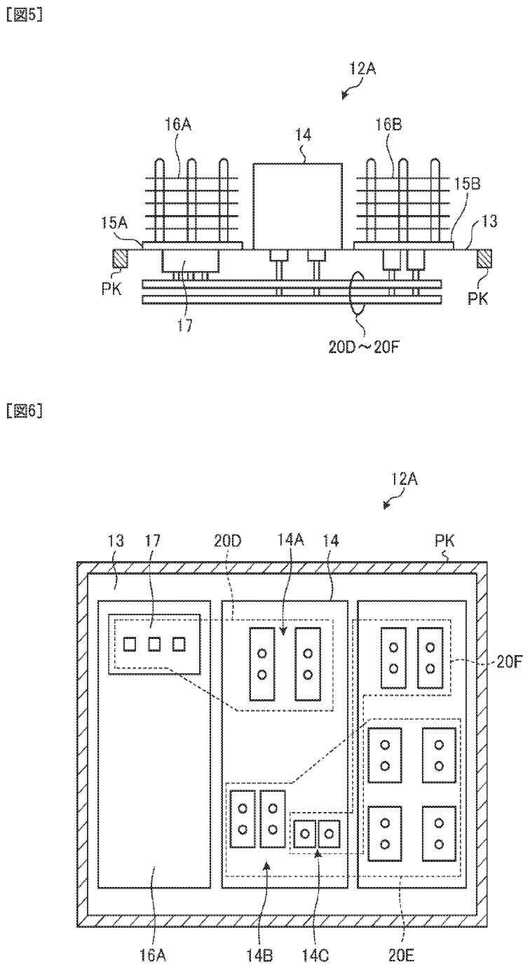

FIG. 5 is a side view of a power conversion unit in a second embodiment.

Parts in FIG. 5 similar to those in FIG. 2 are denoted with the same reference signs.

Referring to FIG. 5, the main part of a high-frequency transformer 14 (excluding its terminal part), cooler bases 15A and 15B, and coolers 16A and 16B are disposed on the top side of a unit frame 13 of the power conversion unit 12 (on the upper side in FIG. 5).

A packing PK disposed along the circumference of the unit frame, a switching element unit 17 disposed in close contact with the cooler base 15A, and a diode unit 18 disposed in close contact with the cooler base 15B are disposed on the back side of the unit frame 13.

In addition, as described below, thin flat conductors 20D to 20F establishing electric connection between each part are disposed on the lower side of the switching element 17 and the diode unit 18.

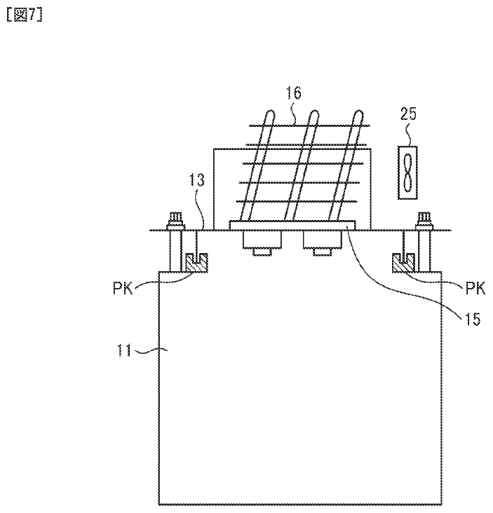

FIG. 6 is a bottom plan view of the unit frame in the second embodiment.

Referring to FIG. 6, for easy understanding, the thin flat conductors 20D to 20F are shown with dashed lines in a see-through manner.

Terminals corresponding to the primary wiring 14A of the high-frequency transformer 14, terminals corresponding to the secondary wiring 14B of the high-frequency transformer 14, and terminals corresponding to the tertiary wiring 14C of the high-frequency transformer 14 protrude on the bottom side of the unit frame 13 of a power conversion unit 12A.

The switching element unit 17 disposed in close contact with the cooler base 15 has terminals protruding. Then, the terminals of the switching element unit 17 and the terminals corresponding to the primary wiring 14A are electrically connected through the thin flat conductor 20D.

The terminals of a first diode rectifier 18A and the terminals of the secondary wiring 14B are electrically connected through the thin flat conductor 20E.

Furthermore, the terminals of a second diode rectifier 18B and the terminals of the tertiary wiring 14C are electrically connected through the thin flat conductor

In this case, for example, the thin flat conductor 20D and the thin flat conductor 20F that do not cross physically are disposed at positions identical in distance from the unit frame 13.

The thin flat conductor 20E and the thin flat conductor 20F that cross physically are disposed at positions different in distance from the unit frame 13. Note that, considering heat generation, desirably, the thin flat conductor 20E for large electric energy is disposed lower than the thin flat conductor 20F in a case where the unit frame is viewed from below.

As illustrated in FIG. 6, the thin flat conductor and the thin flat conductor 20E regarded as large in flowing electric energy each have the shortest possible wiring length to the arrangement of the circuit components.

Thus, suppression can be made in the quantity of heat generation and in inductance.

As described above, according to the present second embodiment, the electric components constituting the power conversion device are made as a single power conversion unit, so that the electric components are disposed physically close to each other, leading to shorter lengths of conductors. That is, because of shorter lengths of current paths, an improvement can be made in conversion efficiency with suppression in the quantity of heat generation and suppression in inductance, leading to a reduction in power consumption.

From among the component terminals of the electric components constituting the power conversion unit 12A, terminals corresponding to a current path for larger electric energy are disposed physically close to each other for a shorter length of conductor, namely, for a shorter length of current path. Thus, an improvement can be made in conversion efficiency with suppression in the quantity of heat generation and suppression in inductance, leading to a reduction in power consumption.

Furthermore, the temperature inside the control box 11 can be inhibited from rising.

### [3] Modification to Embodiments

FIG. 7 is an explanatory view in a modification to the embodiments.

Each embodiment above has been given without consideration of forcible cooling. In the present modification, exemplarily, for forcible cooling, a cooling fan 25 is disposed near the cooling fins of a cooler 16.

According to the present modification, the influence of heat generation can be further suppressed, and a further smaller power conversion unit achieves shorter lengths of conductors. That is, because of shorter lengths of current paths, an improvement can be made in conversion efficiency with suppression in the quantity of heat generation and suppression in inductance, leading to a reduction in power consumption.

The embodiments of the present invention have been described above. However, the embodiments are just exemplary and thus are not intended to limit the scope of the invention. The novel embodiments can be carried out in other various modes. Thus, various omissions, replacements, and alterations can be made without departing from the gist of the invention. The embodiments and modifications thereof are to be included in the scope or gist of the invention and additionally are to be included in the invention in the claims and the scope of equivalents thereof.

For example, in the above description, the control box 11 is assumed to be a member that has a rectangular parallelepiped shape and has a bottom.

However, any shape, such as a cylindrical shape or a hexagonally cylindrical shape, having an opening and a bottom can be adopted, provided that the opening can be occluded with a unit plate that is shaped like a lid and on which electronic components can be mounted such that a sealed part is formed inside.

### REFERENCE SIGNS LIST

10 VEHICULAR POWER CONVERSION DEVICE

11 CONTROL BOX (HOUSING)

12 POWER CONVERSION UNIT 12

13 UNIT FRAME (MEMBER SHAPED LIKE LID)

14 HIGH-FREQUENCY TRANSFORMER

15 COOLER BASE

16 COOLER

17 SWITCHING ELEMENT UNIT

18 DIODE UNIT

18A FIRST DIODE RECTIFIER

18B SECOND DIODE RECTIFIER

20F THIN FLAT CONDUCTOR (FLAT CONDUCTIVE MEMBER)

1. A power conversion device comprising:
a housing;
a panel-shaped unit frame detachably attached to the housing such that an inside of the housing is sealed;
a transformer and a cooler attached to one face of the unit frame and outside the housing, with the unit frame attached to the housing;
an electronic component attached to another face of the unit frame and inside the housing, with the unit frame attached to the housing; and
a flat conductive member electrically connecting the transformer and the electronic component, inside the housing.

2. The power conversion device according to claim 1, wherein
the flat conductive member includes a plurality of flat conductive members, and
the flat conductive member has a shape such that a flat conductive member forming a current path through which current flows for larger electric energy has a shorter effective current path length.

3. The power conversion device according to claim 2, wherein
the flat conductive member is formed such that the flat conductive member forming a current path through which current flows for larger electric energy has a shorter length.

4. The power conversion device according to claim 1, further comprising
a cooling device configured to cool the cooler forcibly.

5. The power conversion device according to claim 1, wherein
the transformer is a high-frequency transformer, and
the electronic component forms a resonance capacitor, a switching element, and a bridge circuit constituting a resonance inverter.
